(19) United States
(12) Patent Application Publication
(10) Pub. No.: US 2024/0349586 A1
(43) Pub. Date: Oct. 17, 2024

(54) PRINTING APPARATUS, METHOD FOR FABRICATING COVER GLASS, AND DISPLAY DEVICE INCLUDING COVER GLASS

(71) Applicant: Samsung Display Co., LTD., Yongin-si (KR)

(72) Inventors: Kyoung In LEE, Yongin-si (KR); Sun HEO, Yongin-si (KR); Sung Yeon HWANG, Yongin-si (KR)

(73) Assignee: Samsung Display Co., LTD., Yongin-si (KR)

(21) Appl. No.: 18/501,153

(22) Filed: Nov. 3, 2023

(30) Foreign Application Priority Data
Apr. 13, 2023 (KR) 10-2023-0048566

(51) Int. Cl. H10K 71/80; H10K 59/80; H10K 77/10

(52) U.S. Cl. CPC H10K 71/80; H10K 59/8792; H10K 77/111; G06F 1/163

(57) ABSTRACT

Provided are printing apparatus, method of fabricating cover glass, and display device including cover glass. A printing apparatus includes a jig including a base including a groove, and a protrusion disposed on a surface of the base, and a pad disposed on the jig. The protrusion surrounds the groove.

### CROSS REFERENCE TO RELATED APPLICATION(S)

This application claims priority to and benefits of Korean Patent Application No. 10-2023-0048566 under 35 U.S.C. § 119, filed on Apr. 13, 2023, in the Korean Intellectual Property Office, the entire contents of which are incorporated herein by reference.

### BACKGROUND

### 1. Technical Field

Embodiments relate to a printing apparatus, a method of fabricating a cover glass, and a display device including the cover glass.

### 2. Description of the Related Art

Display devices become more and more important as multimedia technology is developed. Examples of such display devices include a liquid-crystal display (LCD) device, an organic light-emitting display (OLED) device, etc.

In order to improve aesthetic appeal, flexible display devices that bend their edge portions at a curvature have emerged. Thus, a lot of research on a cover glass including a curved surface has been conducted.

A variety of lines or elements are disposed in a non-display area of a display device. A light-blocking portion is formed in order to hide these elements from the outside. In order to prevent light leakage in the non-display area, a lot of research on a printing apparatus for printing a light-blocking portion on a cover glass and a method of fabricating a cover glass has been conducted.

### SUMMARY

Embodiments provide a printing apparatus capable of printing a curved portion of a cover glass more effectively, and a method of fabricating a cover glass.

Embodiments also provide a printing apparatus capable of preventing light leakage by ensuring a minimum thickness of a light-blocking portion printed on a curved portion of a cover glass.

However, embodiments of the disclosure are not limited to those set forth herein. The above and other embodiments will become more apparent to one of ordinary skill in the art to which the disclosure pertains by referencing the detailed description of the disclosure given below.

According to an aspect of the disclosure, a printing apparatus may include, a jig including a base including a groove, and a protrusion disposed on a surface of the base, and a pad disposed on the jig, wherein the protrusion may surround the groove.

In an embodiment, the protrusion may include a protruding portion surrounding the groove, and a receiving portion surrounded by the protruding portion, and a width of the receiving portion may be larger than a width of the groove.

In an embodiment, at least a portion of the protruding portion may overlap the groove.

In an embodiment, a step portion may be formed between the protruding portion and the groove.

In an embodiment, the protruding portion may be spaced apart from the groove.

In an embodiment, the protruding portion may be spaced apart from the groove by about 5 mm or less.

In an embodiment, the protruding portion may have a shape that is convex away from the groove.

In an embodiment, the protruding portion may include, a first surface spaced apart from the groove, a second surface facing the first surface and being adjacent to the groove, and a third surface between the first surface and the second surface, and the first surface and the second surface may be curved to be convex away from the groove.

In an embodiment, a first distance between a first point, in which the first and third surfaces meet, and a second point, which is an outermost position of the first surface, may be greater than 0 mm.

In an embodiment, an extension direction of the third surface may be perpendicular to an extension direction of the surface of the base.

In an embodiment, the protrusion further may include an opening surrounded by the protruding portion, and a width of the opening may be larger than a width of the pad.

In an embodiment, the protruding portion may include a first extension portion disposed on the base, and a second extension portion extended from the first extension portion, and an extension direction of the first extension portion and an extension direction of the second extension portion are different from each other.

In an embodiment, the extension direction of the second extension portion may be parallel to the extension direction of the surface of the base.

In an embodiment, at least a portion of the second extension portion may overlap the groove.

In an embodiment, the first extension portion may be spaced apart from the groove.

In an embodiment, the groove may include a curved portion having a curvature.

In an embodiment, the protrusion may have a pot shape having a width that decreases as being closer to an upper portion and a lower portion.

According to an aspect of the disclosure, a method of fabricating a cover glass may include, preparing a printing apparatus and a window, the printing apparatus including, a jig including a base including a groove, and a protrusion disposed on a surface of the base, and a pad positioned on the jig and surrounding the groove, and applying ink to the pad and printing the ink on the window.

According to an aspect of the disclosure, a display device may include a cover glass including a light-blocking portion printed by a printing apparatus, the printing apparatus comprising: a jig comprising: a base comprising a groove, and a protrusion disposed on a surface of the base, the protrusion surrounding the groove; and a pad disposed on the jig, and a display panel covered by the cover glass, wherein the cover glass may further include a window that transmits light emitted from the display panel, and the light-blocking portion may be disposed along an edge portion of the window and may at least partially block the light emitted from the display panel.

In an embodiment, a minimum thickness of the light-blocking portion may be equal to or greater than about 2 μm.

According to an embodiment, a curved portion of a cover glass may be printed more effectively.

According to an embodiment, it is possible to prevent light leakage by ensuring a minimum thickness of a light-blocking portion printed on a curved portion of a cover glass.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a printing apparatus according to an embodiment.

FIG. 2 is a schematic plan view of a jig according to an embodiment.

FIG. 3 is a schematic cross-sectional view taken along line X1-X1′ in FIG. 1.

FIG. 4 is an enlarged schematic view of an area A of FIG. 3.

FIG. 5 is a schematic cross-sectional view of a jig according to another embodiment.

FIG. 6 is an enlarged schematic view of an area B of FIG. 5.

FIG. 7 is a schematic cross-sectional view of a jig according to yet another embodiment.

FIG. 8 is an enlarged schematic view of an area C of FIG. 7.

FIG. 9 is a schematic cross-sectional view showing an example of an operating state of the printing apparatus according to the embodiment of FIG. 7.

FIG. 10 is a schematic cross-sectional view showing another example of an operating state of the printing apparatus according to the embodiment of FIG. 7.

FIG. 11 is a schematic cross-sectional view of a jig according to yet another embodiment.

FIG. 12 is an enlarged schematic view of an area D of FIG. 11.

FIG. 13 is a flowchart for illustrating a method of fabricating a cover glass according to an embodiment.

FIG. 14 is a schematic cross-sectional view showing step S100 of FIG. 13.

FIG. 15 is a schematic cross-sectional view showing step S100 of FIG. 13.

FIG. 16 is a schematic cross-sectional view showing step S200 of FIG. 13.

FIG. 17 is a schematic cross-sectional view showing step S200 of FIG. 13.

FIG. 18 is a schematic cross-sectional view showing step S300 of FIG. 13.

FIG. 19 is a schematic cross-sectional view showing step S300 of FIG. 13.

FIG. 20 is a schematic cross-sectional view showing step S400 of FIG. 13.

FIG. 21 is an exploded schematic perspective view of a display device according to an embodiment.

FIG. 22 is a schematic plan view of a display device according to an embodiment.

FIG. 23 is a schematic cross-sectional view of a part of a display device according to an embodiment.

FIG. 24 is a schematic cross-sectional view showing an example of a stack structure of a body unit according to an embodiment.

### DETAILED DESCRIPTION OF THE EMBODIMENTS

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments will be described in detail with reference to the accompanying drawings.

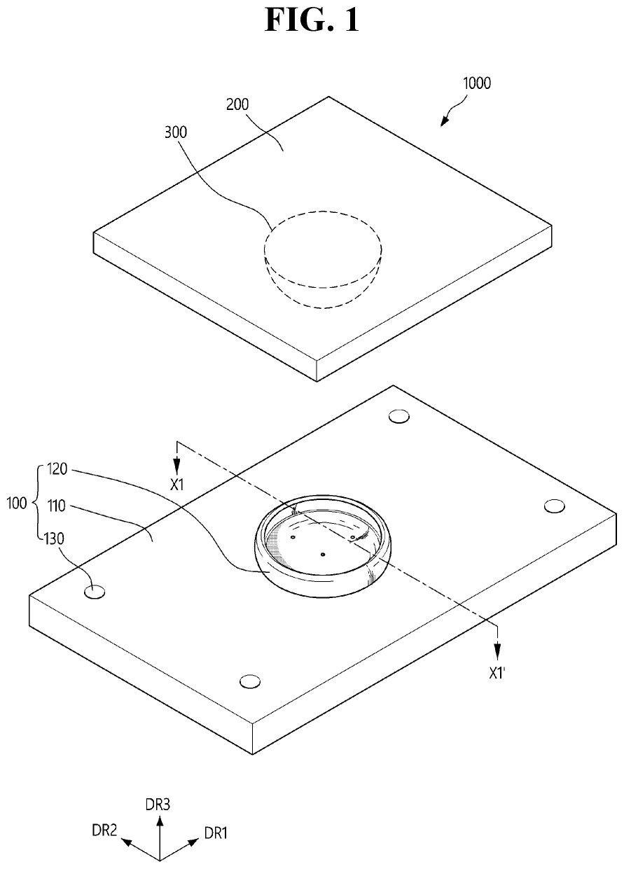

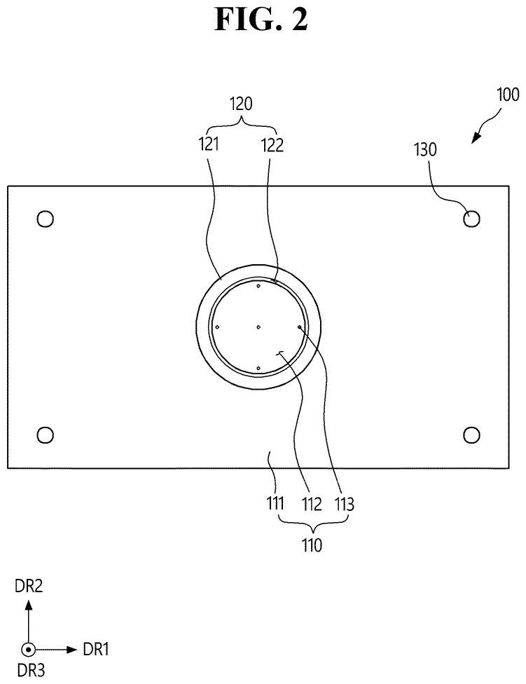

FIG. 1 is a schematic perspective view of a printing apparatus according to an embodiment. FIG. 2 is a schematic plan view of a jig according to an embodiment.

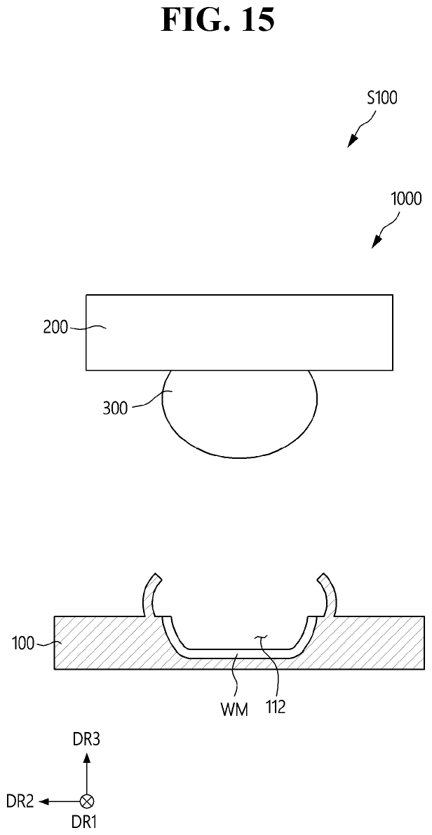

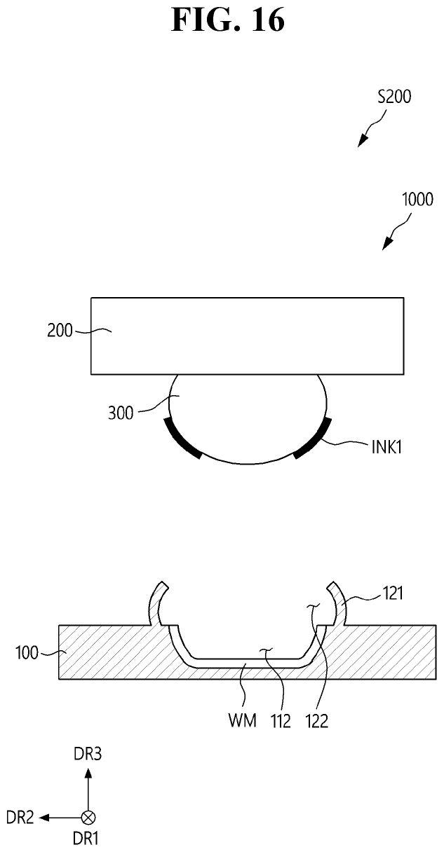

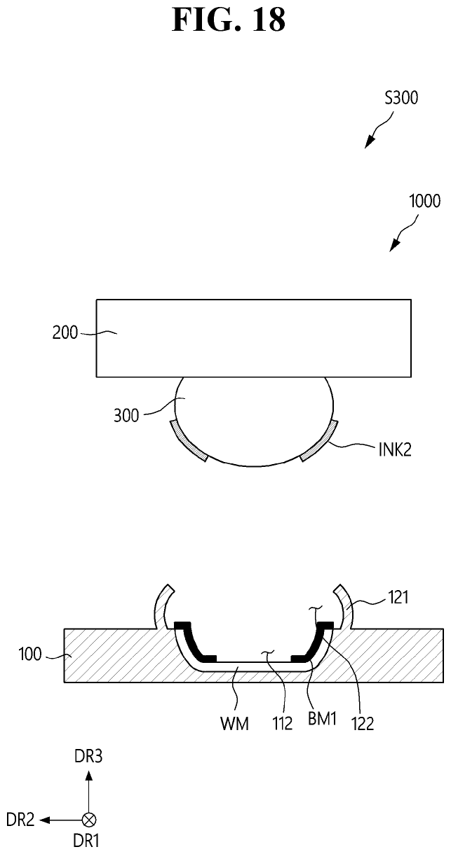

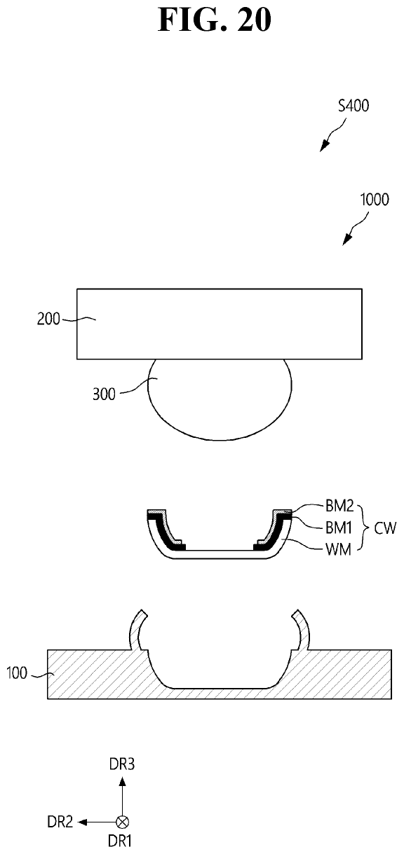

Referring to FIGS. 1 and 2, a printing apparatus 1000 may print an ink on the outer surface of a cover glass. For example, the printing apparatus 1000 may be used for printing ink INK1 and INK2 (see FIGS. 16 and 18) on the outer surface of a window WM (see FIG. 15) in order to form light-blocking portions BM1 and BM2 (see FIG. 20) of the cover glass CW (see FIG. 20), which will be described later.

The printing apparatus 1000 may include a jig 100, a print head 200 positioned above the jig 100, and a pad 300 disposed on a side of the print head 200.

The jig 100 may support a print object such as a window WM (see FIG. 18) seated thereon. The jig 100 may include a base 110, a protrusion 120 disposed on the base 110, and fastening holes 130.

The base 110 may provide a space in which an object is seated. The base 110 may support the object, the print head 200 and the pad 300 during a printing process. The base 110 may withstand (or hold up) the pressing force applied from the print head 200.

The base 110 may include a body 111, a groove 112, and adsorption holes 113.

The body 111 may form the outer shape of the base 110. The groove 112 may be positioned on a surface of the body 111, and the adsorption holes 113 penetrating the body 111 from the groove 112 may be formed inside the thickness of the body 111.

The groove 112 may be a space in which an object is accommodated. The shape of the groove 112 may conform to (or similar to) the shape of the object. For example, the groove 112 may have a circular shape when viewed from the top (or in plan view), but embodiments are not limited thereto. The width of the groove 112 may be substantially equal to the width of the object. The upper surface of the groove 112 may be in contact with (e.g., in direct contact with) a surface of the object.

The adsorption holes 113 may be passages through which air moves. The adsorption holes 113 may be formed by penetrating through the body 111 in the thickness direction from the upper surface of the body 111 in the groove 112. As shown in the drawings, the adsorption holes 113 may include two or more small holes), but embodiments are not limited thereto. For example, the adsorption hole 113 may include one large hole.

For example, in case that the printing apparatus 1000 includes a vacuum adsorption unit, the adsorption holes 113 may be passages through which air is absorbed by the vacuum adsorption unit and discharged to the outside. After an object is accommodated in the groove 112, the vacuum adsorption unit sucks air through the adsorption holes 113 so that the object and the body 111 may be in tight contact, and the object may be fixed in the groove 112.

The protrusion 120 may be disposed on the base 110. The protrusion 120 may be disposed between the base 110 and the print head 200. The protrusion 120 may be integral with the base 110 or may be physically separated from the base 110.

The protrusion 120 may conform to (or similar to) the shape of the object. For example, in case that the object is in a circular shape when viewed from the top (or in plan view), the protrusion 120 may be in a circular shape when viewed from the top (or in plan view) as shown in the drawings. However, embodiments are not limited thereto. The protrusion 120 may have a variety of shapes such as a polygonal shape and an elliptical shape.

The protrusion 120 may include a protruding portion (or a partition wall) 121 and a receiving portion (or receiving space) 122.

The protruding portion 121 may be disposed to surround the groove 112 of the base 110. For example, the protrusion 120 may surround (e.g., completely surround) the groove 112 when viewed from the top (or in plan view).

According to an embodiment, the protruding portion 121 may have a shape in which a side surface is convex outward. For example, the protruding portion 121 may have a pot shape having a narrow upper portion, a narrow lower portion, and a wide middle portion in the third direction DR3.

Here, the outward direction and the inward direction of the protruding portion 121 refer to the direction away from the receiving portion 122 and the direction toward the receiving portion 122, respectively.

The receiving portion 122 may be the space surrounded by the protruding portion 121. The receiving portion 122 may be larger than the groove 112 when viewed from the top (or in plan view). The accommodating portion 122 may accommodate the pad 300 during a printing process.

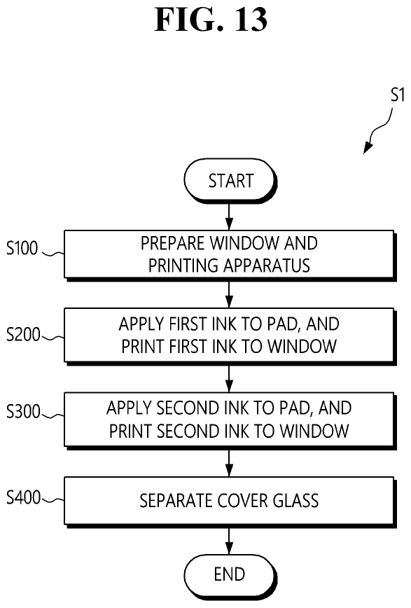

The protrusion 120 may prevent the shape of the pad 300 from being excessively spread in the first and second directions DR1 and DR2 in case that the print head 200 is pressed during the printing process. This will be described with reference to FIG. 13 and the like along with a description of a method S1 of fabricating a cover glass (see FIG. 13) according to an embodiment.

In the drawings, the first direction DR1 and the second direction DR2 intersect each other as the horizontal directions. For example, the first direction DR1 and the second direction DR2 may be perpendicular to each other. For example, a third direction DR3 may intersect the first direction DR1 and the second direction DR2, and may be a vertical direction, for example. Here, the side indicated by the arrow of each of the first to third directions DR1, DR2 and DR3 may be referred to as a first side, and the opposite side may be referred to as a second side.

In the fastening holes 130, fasteners for fixing the base 110 may be disposed. For example, the printing apparatus 1000 may further include a stage. The base 110 may be disposed on the stage, and the base 110 may be fixed to the stage by inserting the fasteners into the fastening holes 130.

The print head 200 may be disposed on the jig 100. The print head 200 may be disposed such that the print head 200 faces the jig 100 along the third direction DR3. For example, the print head 200 may be positioned above the jig 100. The shape of the print head 200 may conform to (or similar to) the shape of the jig 100. The print head 200 may be larger than the object, and may be smaller than the jig 100.

For example, the print head 200 may move in a certain direction through a separate driver. For example, the print head 200 may reciprocate toward and away from the jig 100, e.g., in the third direction DR3.

The pad 300 may be disposed on a surface (e.g., lower surface) of the print head 200. The pad 300 may be disposed between the print head 200 and the jig 100. The shape of the pad 300 may conform to (or similar to) the shape of the object and the shape of the protrusion 120. For example, the pad 300 may have a hemispherical shape or a circular shape when viewed from the top (or in plan view). However, embodiments are not limited thereto. The pad 300 may have a variety of shapes.

Ink may be applied to the surface of the pad 300. As the surface of the pad 300, to which the ink is applied, comes into contact with the object, the ink may be printed on the object.

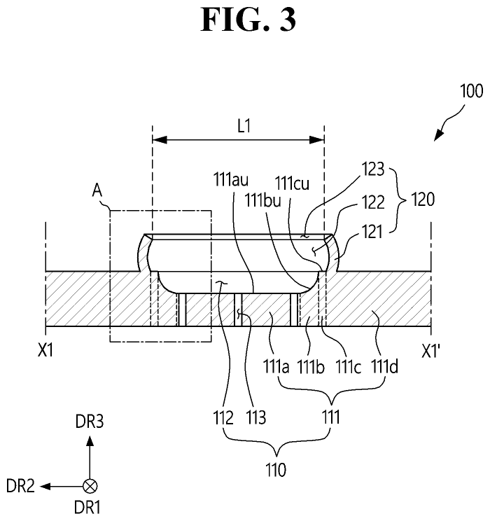

The pad 300 may include a material having elasticity and stretchability. Therefore, during the printing process, the shape of the pad 300 may be changed inside the receiving portion 122 (see FIG. 3) of the protrusion 120 by the pressure of the print head 200. For example, the pad 300 may be pressured by the print head 200 so that the width of the pad in the third direction DR3 may decrease and the widths in the direction DR1 and the second direction DR2 may increase in the receiving portion 122 of the protrusion 120 (see FIG. 3).

FIG. 3 is a schematic cross-sectional view taken along line X1-X1′ in FIG. 1.

Referring to FIG. 3 in conjunction with FIGS. 1 and 2, the jig 100 may include the base 110 and the protrusion 120 disposed on the base 110.

The base 110 may include the body 111, the groove 112, and the adsorption holes 113.

The body 111 may include a central portion 111a, an edge portion 111b, a support portion 111c, and an auxiliary portion 111d.

The central portion 111a may be positioned at the center portion of the body 111. An upper surface 111au of the central portion 111a may be generally flat. The groove 112 may be positioned on the central portion 111a. The upper surface 111au of the central portion 111a may be in contact with (e.g., in direct contact with) a surface of an object during a printing process.

The edge portion 111b may be positioned on a side of the central portion 111a. The edge portion 111b may surround the central portion 111a when viewed from the top (or in plan view). An upper surface 111bu of the edge portion 111b may be recessed in a direction opposite to the third direction DR3. The upper surface 111bu of the edge portion 111b may be a curved surface having at least one curvature. The groove 112 may be disposed on the edge portion 111b. The upper surface 111bu of the edge portion 111b may be in contact with (e.g., in direct contact with) a surface of an object during a printing process.

The support portion 111c may be positioned on a side of the edge portion 111b. The support portion 111c may surround the edge portion 111b when viewed from the top (or in plan view). An upper surface 111cu of the support portion 111c may be generally flat. The receiving portion 122 of the protrusion 120 may be disposed on the support portion 111c. The upper surface 111cu of the support portion 111c may be in direct contact with the pad 300 during the printing process.

The auxiliary portion 111d may be positioned on a side of the support portion 111c. The auxiliary portion 111d may surround the support portion 111c when viewed from the top (or in plan view). The upper surface 111du of the auxiliary portion 111d may be generally flat. The protruding portion 121 of the protrusion 120 may be disposed on the auxiliary portion 111d.

The groove 112 may be the space in which an object is accommodated. The groove 112 may be formed concavely in the upper surface of the body 111 in the direction opposite to the third direction DR3. For example, the groove 112 may be defined (or formed) by the upper surfaces of the central portion 111a and the edge portion 111b of the body 111. The height of the groove 112 may be substantially equal to the height or thickness of the object.

The adsorption holes 113 may be positioned in the central portion 111a of the body 111. However, embodiments are not limited thereto. The adsorption holes 113 may be positioned at the edge portion 111b of the body 111. The adsorption holes 113 may penetrate in the thickness direction of the body 111, e.g., in the third direction DR3. The adsorption holes 113 may be positioned under the groove 112. The adsorption holes 113 may be formed by penetrating through the body 111 in the thickness direction from the upper surface of the body 111 in the groove 112.

The protrusion 120 may include the protruding portion 121, the receiving portion 122, and an opening 123.

The protruding portion 121 may be disposed on the auxiliary portion 111d. The protruding portion 121 may surround the receiving portion 122. According to an embodiment, the protruding portion 121 may have a shape in which a side surface is convex outward. For example, the protruding portion 121 may have a pot shape having a narrow upper portion, a narrow lower portion, and a wide middle portion in the third direction DR3. In a cross-sectional view, the protruding portion 121 may have an arch shape.

The receiving portion 122 may be disposed on the groove 112. The receiving portion 122 may be surrounded by the protruding portion 121. The receiving portion 122 may conform to (or similar to) the shape of the protruding portion 121.

The receiving portion 122 may be larger than the groove 112. Accordingly, the receiving portion 122 may overlap not only the central portion 111a and the edge portion 111b of the body 111 but also the support portion 111c.

The opening 123 may be positioned at the top portion of the receiving portion 122. During the printing process, the pad 300 may move into the receiving portion 122 through the opening 123. The width (or diameter) L1 of the opening 123 may be large enough so that the pad 300 may pass through it. The width L1 of the opening 123 may be greater than the width (or diameter) of the pad 300. However, embodiments are not limited thereto. Since the pad 300 has elasticity and flexibility, the shape of the pad 300 may be changed as the pad 300 is brought into contact with the protruding portion 121. Therefore, in case that the width L1 of the opening 123 is smaller than the width of the pad 300, the pad 300 may pass through the opening 123 and move into the receiving portion 122 unless the difference in width is large.

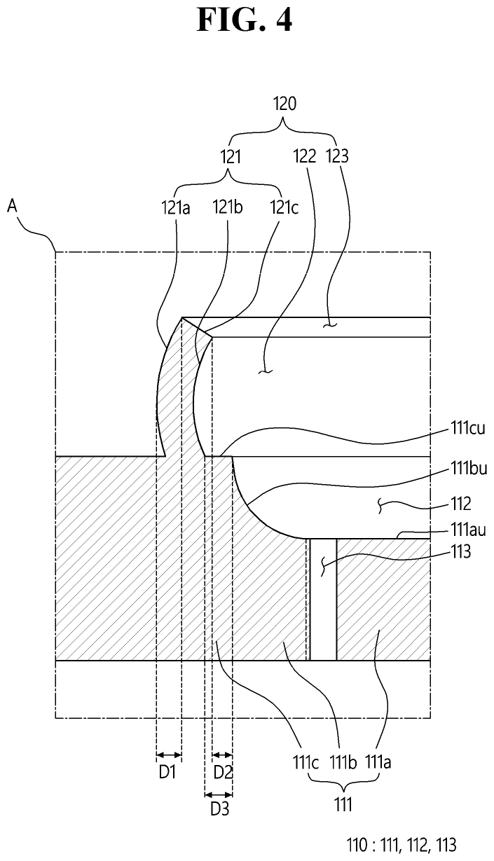

FIG. 4 is an enlarged schematic view of an area A of FIG. 3.

Referring to FIG. 4, the protruding portion 121 may include an outer surface 121a, an inner surface 121b, and an end surface 121c.

The outer surface 121a may be positioned away from the receiving portion 122. The inner surface 121b may be adjacent to the receiving portion 122. The end surface 121c may be positioned at an end portion of the opposite side of the body 111. The end surface 121c may be disposed between the outer surface 121a and the inner surface 121b. The end surface 121c may surround the inner surface 121b, and the outer surface 121a may surround the end surface 121c and the inner surface 121b when viewed from the top (or in plan view).

The outer surface 121a and the inner surface 121b may be convex outward, e.g., away from the receiving portion 122. Accordingly, the receiving portion 122 may have a pot shape having smaller widths in the upper portion and the lower portion and a larger width in the middle portion.

The end surface 121c may not be parallel to the upper surface of the body 111. For example, the extension direction of the end surface 121c may be different from the extension direction of the upper surface of the body 111.

The upper portion and the lower portion of the outer surface 121a and the upper portion and the lower portion of the inner surface 121b may be closer to the center portion of the receiving portion 122, and the middle portion may be positioned farther from the center portion of the receiving portion 122. The end surface 121c may overlap the support portion 111c and the auxiliary portion 111d in the third direction DR3. The end surface 121c may not overlap the central portion 111a, the edge portion 111b, and/or the groove 112 in the third direction DR3.

In the printing apparatus 1000, since the shape of the protruding portion 121 is convex outward, it is possible to more effectively print a curved portion of an object such as a cover glass.

For example, during a printing process by a method S1 of fabricating a cover glass (see FIG. 13) to be described later, the pad 300 may be pressed by the print head 200 so that the width of the pad in the third direction DR3 may decrease and the widths in the direction DR1 and the second direction DR2 may increase in the receiving portion 122.

Since the protruding portion 121 is disposed around the receiving portion 122, it is possible to prevent the widths of the pad 300 in the first and second directions DR1 and DR2 from increasing. The protruding portion 121 may exert (or apply) a repulsive force on the pressure received from the pad 300 according to the action-reaction law (or principle). The repulsive force generated from the protruding portion 121 may be applied as additional pressure to the object, and thus the curved portion of the object may be more effectively printed.

In the printing apparatus 1000, the shape of the protruding portion 121 may be convex outward, so that the repulsive force generated from the inner surface 121b may act not only in the horizontal direction but also in the downward direction where the object is positioned.

As a result, the repulsive force generated downward by the protruding portion 121 may be added to apply a stronger pressing force to the curved portion of the object, so that the curved portion of the object may be printed even more effectively.

A first distance D1, which is the horizontal distance between the point, in which the outer surface 121a and the end surface 121c meet, and the outermost point of the outer surface 121a, may be greater than 0 mm. For example, a second distance D2, which is the horizontal distance between the point where the inner surface 121b and the end surface 121c meet, and the point where the support portion 111c and the edge portion 111b meet, may be about 5 mm or less. The first and second distances D1 and D2 may refer to the shortest distances between the points.

In the printing apparatus 1000, the curvature of the outer surface 121a may increase as the first distance D1 increases, and accordingly, the direction of the repulsive force generated from the protruding portion 121 may act further downward. As the second distance D2 in the outward direction decreases, the repulsive force generated from the protruding portion 121 may be more effectively transmitted to the object positioned in the groove 112.

The repulsive force acting toward the groove 112 from the protruding portion 121 may allow the curved portion of the object to be printed more effectively.

The jig 100 may include a step portion positioned on a side of the groove 112 due to the support portion 111c. For example, the protruding portion 121 may be spaced apart from the groove 112 by a distance (or selectable distance), for example, the width D3 of the support portion 111c. Accordingly, a step portion may be formed between the protruding portion 121 and the groove 112.

In the printing apparatus 1000, the width D3 of the support portion 111c may be about 5 mm or less. As the width of the support portion 111c decreases, the repulsive force generated from the protruding portion 121 may be more effectively transmitted to the object positioned in the groove 112.

Hereinafter, printing apparatuses according to other embodiments will be described. In the following description, the same or similar elements will be denoted by the same or similar reference numerals, and redundant descriptions will be omitted or briefly described for descriptive convenience.

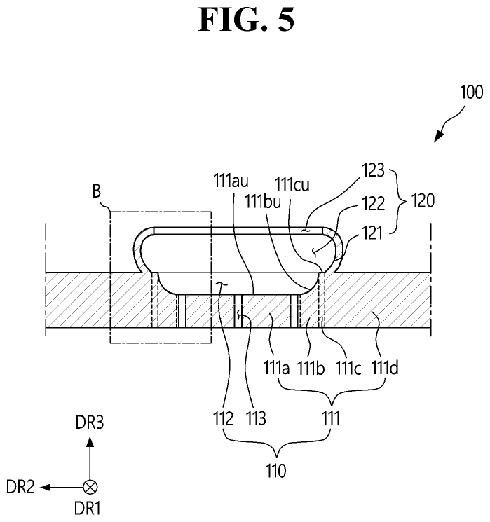

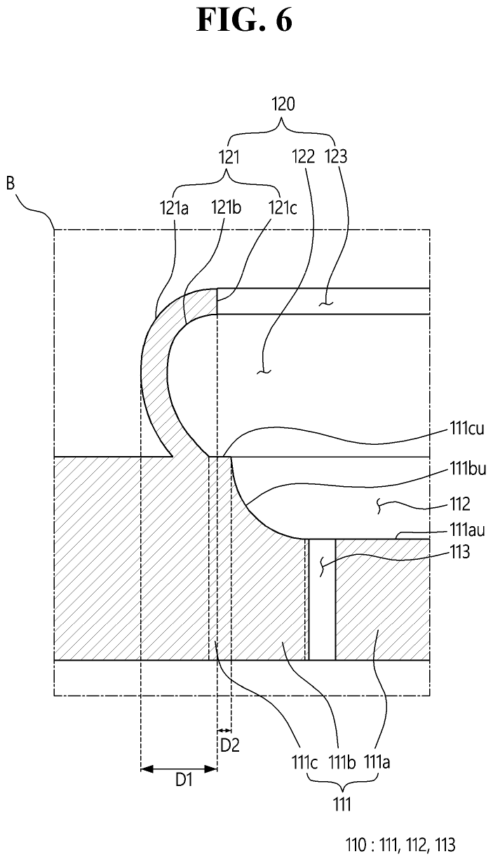

FIG. 5 is a schematic cross-sectional view of a jig according to another embodiment. FIG. 6 is an enlarged schematic view of an area B of FIG. 5.

A printing apparatus 1000 according to the embodiment of FIGS. 5 and 6 is different from the printing apparatus 1000 according to the embodiment of FIG. 3 and the like in that an end surface 121c of a protruding portion 121 is perpendicular to the upper surface of a base 110, and the curvature of the protruding portion 121 is larger.

For example, the end surface 121c of the protruding portion 121 may be perpendicular to the upper surface of the base 110. For example, the tangent line at the point where the outer surface 121a and the end surface 121c meet and the tangent line at the point where the inner surface 121b and the end surface 121c meet may be in parallel to the upper surface of the base 110.

For example, even though the second distance D2, which is the horizontal distance between the point where the inner surface 121b and the end surface 121c meet, and the point where the support portion 111c and the edge portion 111b meet, is constant, the first distance D1, which is the horizontal distance between the point where the outer surface 121a and the end surface 121c meet, and the outermost point of the outer surface 121a, may increase.

The curvature of the outer surface 121a and the inner surface 121b of the printing apparatus 1000 according to an embodiment may be greater than that of the printing apparatus 1000 according to the embodiment described above with reference to FIG. 3 and the like. As described above, as the first distance D1 increases, the curvature of the outer surface 121a increases, and accordingly, the direction of the repulsive force generated from the protruding portion 121 may act further downward. The repulsive force acting in the downward direction may allow the curved portion of the object to be printed more effectively.

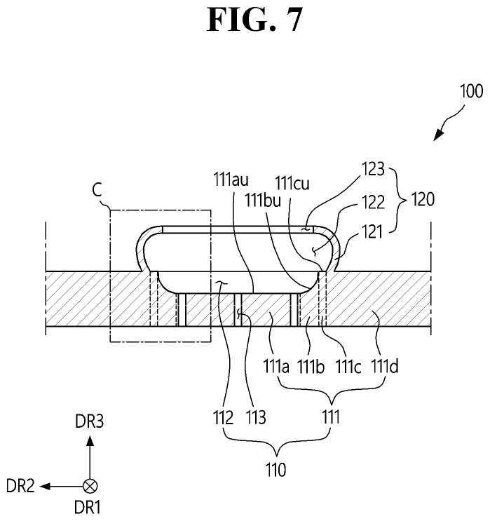

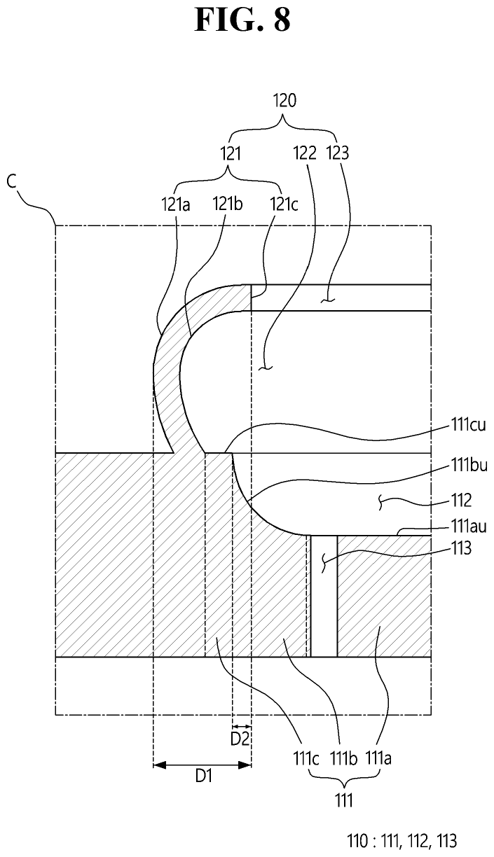

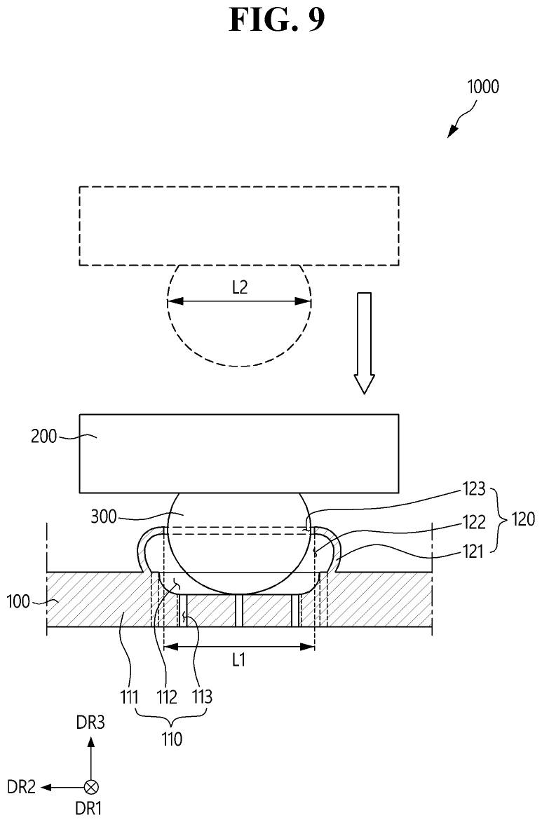

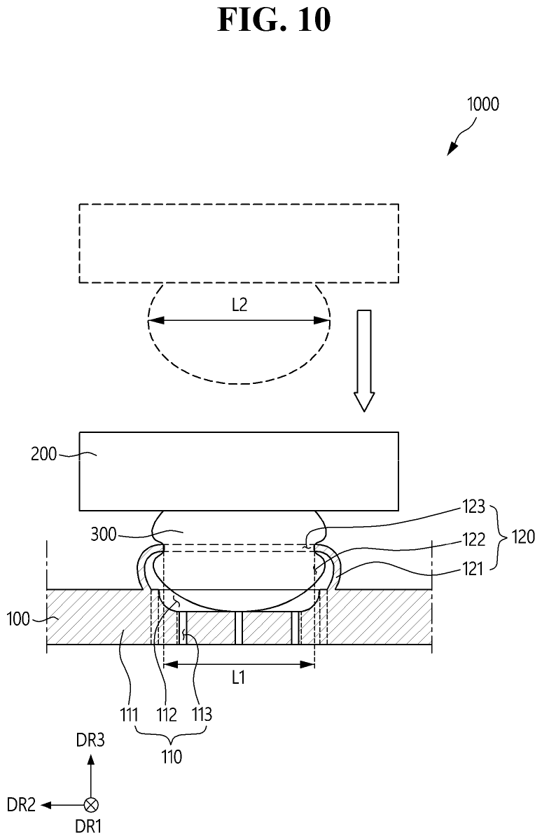

FIG. 7 is a schematic cross-sectional view of a jig according to yet another embodiment. FIG. 8 is an enlarged schematic view of an area C of FIG. 7. FIG. 9 is a schematic cross-sectional view showing an example of an operating state of the printing apparatus according to the embodiment of FIG. 7. FIG. 10 is a schematic cross-sectional view showing another example of an operating state of the printing apparatus according to the embodiment of FIG. 7.

The printing apparatus 1000 according to the embodiment of FIGS. 7 and 8 is different from the printing apparatus 1000 according to the embodiment described above with reference to FIGS. 3, 5, and the like in that a protruding portion 121 of a jig 100 overlaps a groove 112.

For example, an end portion of the protruding portion 121, i.e., the end portion positioned on the opposite side of the base 110 may be further extended in the first direction DR1 and the second direction DR2, so that the end portion of the protruding portion 121 may overlap the groove 112 and the third direction DR3.

Accordingly, in the printing apparatus 1000, since the first distance D1 further increase, the repulsive force generated from the protruding portion 121 may act further downward. As the second distance D2 in the inward direction increases, the repulsive force generated from the protruding portion 121 may be more effectively transmitted to the object positioned in the groove 112. The repulsive force acting toward the groove 112 from the protruding portion 121 may allow the curved portion of the object to be printed more effectively.

Although the end surface 121c is perpendicular to the upper surface of the base 110 as in the example shown in FIG. 5, the same effect may be achieved in case that the end surface 121c is oblique with respect to the upper surface of the base 110 as long as the protruding portion 121 overlaps the groove 112.

Referring to FIG. 9, according to an embodiment, the width L2 of the pad 300 may be smaller than the width L1 of the opening 123 positioned between the end surfaces 121c facing each other. In case that the print head 200 descends, the pad 300 may move into the receiving portion 122 and the groove 112 without contact with the end surface 121c of the protruding portion 121.

Referring to FIG. 10, according to another embodiment, the width L2 of the pad 300 may be substantially equal to or greater than the width L1 of the opening 123 positioned between the end surfaces 121c facing each other. In case that the print head 200 descends, the pad 300 may be in contact with the end surface 121c of the protruding portion 121. Since the pad 300 has elasticity and stretchability, the pad 300 may move into the receiving portion 122 and the groove 112 with changing its shape in case that the pad 300 is in contact with the end surface 121c.

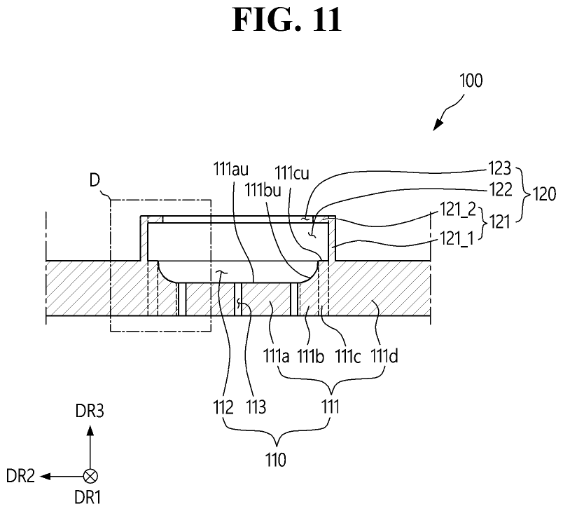

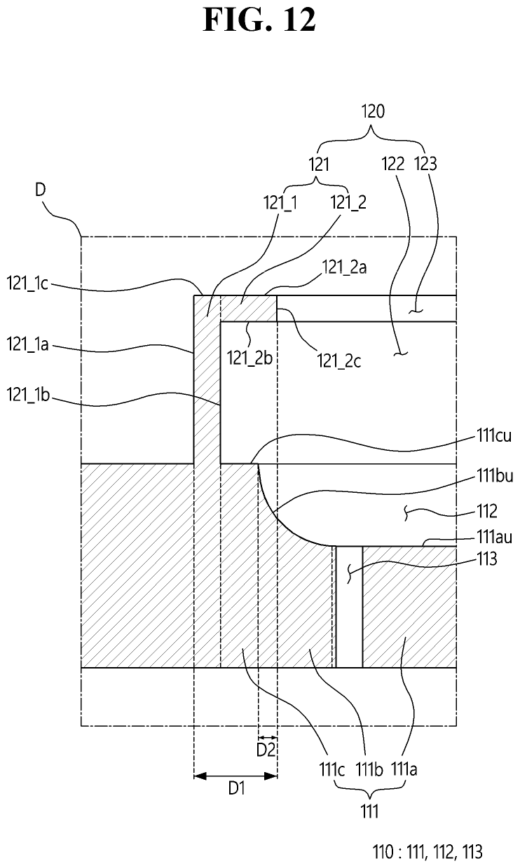

FIG. 11 is a schematic cross-sectional view of a jig according to yet another embodiment. FIG. 12 is an enlarged schematic view of an area D of FIG. 11.

The printing apparatus 1000 according to the embodiment of FIGS. 11 and 12 is different from the printing apparatus 1000 according to the embodiment described above with reference to FIGS. 3, 5, 7, and the like in that a protruding portion 121 includes a first extension portion 121_1 and a second extension portion 121_2.

For example, the protruding portion 121 may have an ‘L’ shape in a cross-sectional view. For example, the protruding portion 121 may include a first extension portion 121_1 and a second extension portion 121_2. According to an embodiment, each of the first extension portion 121_1 and the second extension portion 121_2 may be implemented as a straight wall with flat surfaces.

The first extension portion 121_1 may protrude from the body 111 of the base 110 in a direction different from the extension direction of the base 110. Although the extension direction of the first extension portion 121_1 is perpendicular to the extension direction of the body 111 in the example shown in the drawing, but embodiments are not limited thereto. The extension direction of the first extension portion 121_1 may be oblique to the extension direction of the body 111. The extension direction of the first extension portion 121_1 may be oblique to the extension direction of the body 111.

The first extension portion 121_1 may be disposed on the auxiliary portion 111d of the body 111. The first extension portion 121_1 may be disposed on a side of the groove 112. The first extension portion 121_1 may be disposed to surround the groove 112 when viewed from the top (or in plan view). The first extension portion 121_1 may conform to (or similar to) the shape of the groove 112 when viewed from the top (or in plan view). For example, the first extension portion 121_1 may have a circular shape when viewed from the top (or in plan view), like the groove 112, but embodiments are not limited thereto.

The second extension portion 121_2 may protrude from the first extension portion 121_1 in a direction different from the extension direction of the first extension portion 121_1. Although the extension direction of the second extension portion 121_2 is perpendicular to the extension direction of the first extension portion 121_1 in the example shown in the drawing, embodiments are not limited thereto. The extension direction of the second extension portion 121_2 may be oblique to the extension direction of the first extension portion 121_1.

The second extension portion 121_2 may be positioned adjacent to an end portion of the first extension portion 121_1, i.e., the opposite end portion of the base 110. However, embodiments are not limited thereto. The second extension portion 121_2 may be positioned in the middle portion of the first extension portion 121_1.

When the jig 100 is viewed from the top (or in plan view), the second extension portion 121_2 may cover (e.g., entirely cover) the support portion 111c of the body 111 and a part of the edge portion 111b. The second extension portion 121_2 may be disposed on a side of the first extension portion 121_1 when viewed from the top (or in plan view). The second extension portion 121_2 may conform to (or similar to) the shape of the first extension portion 121_1 when viewed from the top (or in plan view). For example, the second extension portion 121_2 may have a shape with an empty center, like a donut when viewed from the top (or in plan view), but embodiments are not limited thereto.

Although the end portion of the second extension portion 121_2 overlaps the groove 112 in the example shown in FIG. 7, embodiments are not limited thereto. The second extension portion 121_2 may overlap only the support portion 111c of the body 111, but may not overlap the groove 112. For example, the second extension portion 121_2 may cover only a part of the support portion 111c of the body 111 when the jig 100 is viewed from the top (or in plan view).

The first extension portion 121_1 and the second extension portion 121_2 may include outer surfaces 121_1a and 121_2a, inner surfaces 121_1b and 121_2b, and end surfaces 121_1c and 121_2c, respectively.

The outer surface 121_1a of the first extension portion 121_1 may be positioned away from the receiving portion 122. The inner surface 121_1b of the first extension portion 121_1 may be adjacent to the receiving portion 122. The end surface 121_1c of the first extension portion 121_1 may be positioned on an end portion of the opposite side of the body 111.

According to an embodiment, the outer surfaces 121_1a and 121_2a, the inner surfaces 121_1b and 121_2b, and the end surfaces 121_1c and 121_2c of the first extension portion 121_1 and the second extension portion 121_2, respectively, may be flat surfaces.

The printing apparatus 1000 according to an embodiment may include the first extension portion 121_1 and the second extension portion 121_2, so that the repulsive force generated from the protruding portion 121 may act in the first direction DR1 and the second direction DR1, as well as in the third direction DR3, i.e., in the downward direction. As a result, the curved portion of the object may be printed even more effectively.

Although the end surface 121_2c of the second extension portion 121_2 is perpendicular to the upper surface of the base 110 in the example shown in FIG. 5, embodiments are not limited thereto. The end surface 121_2c of the second extension portion 121_2 may be oblique to the upper surface of the base 110.

Hereinafter, a method of fabricating a cover glass by using the printing apparatus 1000 according to the above-described embodiments will be described.

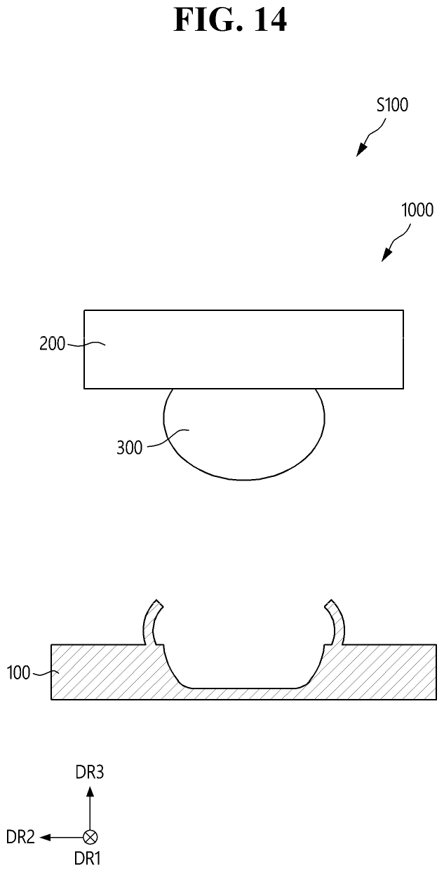

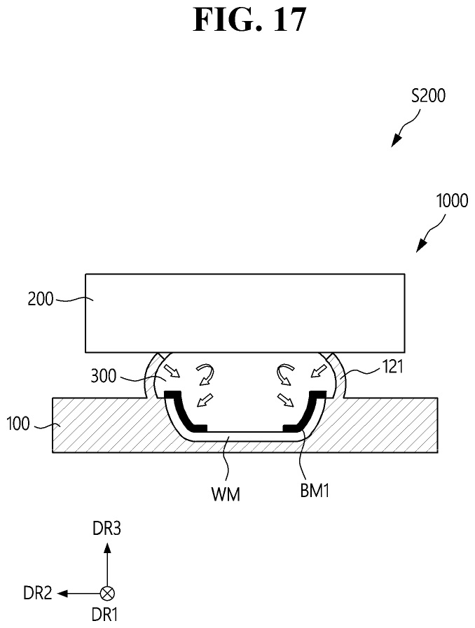

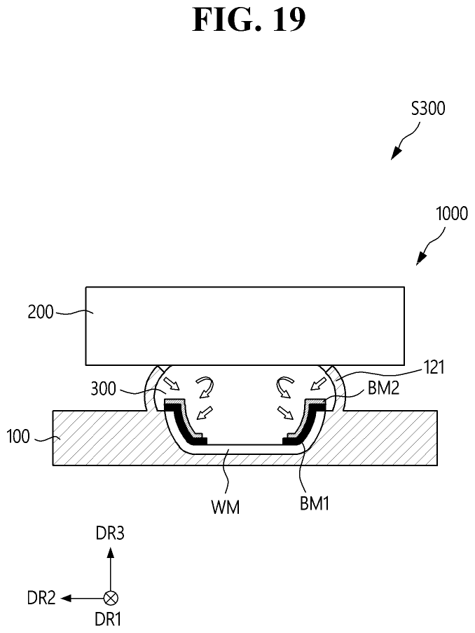

FIG. 13 is a flowchart for illustrating a method of fabricating a cover glass according to an embodiment. FIG. 14 is a schematic cross-sectional view showing step S100 of FIG. 13. FIG. 15 is a cross-sectional view showing step S100 of FIG. 13. FIG. 16 is a schematic cross-sectional view showing step S200 of FIG. 13. FIG. 17 is a schematic cross-sectional view showing step S200 of FIG. 13. FIG. 18 is a cross-sectional view showing step S300 of FIG. 13. FIG. 19 is a schematic cross-sectional view showing step S300 of FIG. 13. FIG. 20 is a schematic cross-sectional view showing step S400 of FIG. 13.

Referring to FIGS. 13 to 20, a method S1 of fabricating a cover glass according to an embodiment may include preparing a window and a printing apparatus (step S100); applying a first ink to a pad and printing the first ink on a window (step S200); applying a second ink to the pad and printing the second ink on the window (step S300); and separating a cover glass (step S400).

As shown in FIGS. 14 and 15, in the preparing of the window and the printing apparatus 1000 (step S100), a window WM may be seated in a groove 112 of a jig 100 of the prepared printing apparatus 1000.

As shown in FIGS. 16 and 17, in the applying of the first ink to the pad and printing the first ink on the window WM (step S200), the first ink INK1 may be applied to a surface of the pad 300. The first ink INK1 may be applied on a surface of the pad 300 overlapping the curved portion of the window WM.

The first ink INK1 may function as a background ink that is directly seen from the front side (or lower side in the drawing) of the window WM. The first ink INK1 may include at least one of an epoxy-based resin and a polyester-based resin. The first ink INK1 may include a light-blocking material such as a black pigment capable of blocking light.

As the print head 200 descends, the pad 300 may move into the groove 112 and the receiving portion 122 of the jig 100. The first ink INK1 applied to the pad 300 may be in contact with the curved portion of the window WM. A first light-blocking portion BM1 may be formed on the window WM by printing the first ink INK1.

The pad 300 may be pressed by the print head 200 so that the width of the pad in the third direction DR3 may decrease and the widths in the direction DR1 and the second direction DR2 may increase.

According to the method S1 of fabricating a cover glass of this embodiment, the protruding portion 121 may prevent the widths of the pad 300 in the first and second directions DR1 and DR2 from increasing. The protruding portion 121 may exert (or apply) a repulsive force on the pressure received from the pad 300 according to the action-reaction law. The repulsive force generated from the protruding portion 121 may be applied as additional pressure to the object, and thus the curved portion of the object may be more effectively printed.

As described above, according to the above-described embodiments, the protruding portion 121 may generate the repulsive force downward to apply a stronger pressing force to the curved portion of the object, so that the curved portion of the object may be printed even more effectively.

As shown in FIGS. 18 and 19, in the applying of the second ink to the pad and printing the second ink on the window WM (step S300), the second ink INK2 may be applied to a surface of the pad 300. The second ink INK2 may be applied on the surface of the pad 300 overlapping the curved portion of the window WM and the first light-blocking portion BM1.

The second ink INK2 may be applied on a surface of the first light-blocking portion BM1 to function as a shielding ink. The second ink INK2 may include at least one of an epoxy-based resin and an acrylic-based resin. The second ink INK2 may include a light-blocking material such as a black pigment capable of blocking light.

As the print head 200 descends, the pad 300 may move into the groove 112 and the receiving portion 122 of the jig 100. The second ink INK2 applied to the pad 300 may be in contact with the curved portion of the first light-blocking portion BM1. The second light-blocking portion BM2 may be formed on the first light-blocking portion BM1 by printing the second ink INK2.

The pad 300 may be pressed by the print head 200 so that the width of the pad in the third direction DR3 may decrease and the widths in the direction DR1 and the second direction DR2 may increase.

According to the method S1 of fabricating a cover glass of this embodiment, the protruding portion 121 may prevent the widths of the pad 300 in the first and second directions DR1 and DR2 from increasing. The protruding portion 121 may exert (or apply) a repulsive force on the pressure received from the pad 300 according to the action-reaction law. The repulsive force generated from the protruding portion 121 may be applied as additional pressure to the object, and thus the curved portion of the object may be more effectively printed.

As described above, according to the above-described embodiments, the protruding portion 121 may generate the repulsive force downward to apply a stronger pressing force to the curved portion of the object, so that the curved portion of the object may be printed even more effectively.

As shown in FIG. 20, in the separating of the cover glass CW (step S400), the cover glass CW may be separated from the printing apparatus 1000 after the printing.

The cover glass CW may include the window WM, the first light-blocking portion BM1 disposed on the window WM, and the second light-blocking portion BM2 disposed on the first light-blocking portion BM1. The first light-blocking portion BM1 and the second light-blocking portion BM2 may be disposed on a surface of the cover glass CW that is opposite to the display surface (e.g., lower surface in the drawing).

The first light-blocking portion BM1 and the second light-blocking portion BM2 may be disposed on the curved portion of the window WM. The minimum thickness of the first light-blocking portion BM1 and the second light-blocking portion BM2 may be substantially equal to or greater than about 2 μm.

According to the method S1 of fabricating the cover glass of this embodiment, it is possible to prevent light leakage by ensuring the minimum thickness of the first and second light-blocking portions BM1 and BM2 printed on the cover glass CW.

Hereinafter, a display device including a cover glass fabricated using the printing apparatus 1000 and the method S1 according to the above-described embodiments will be described.

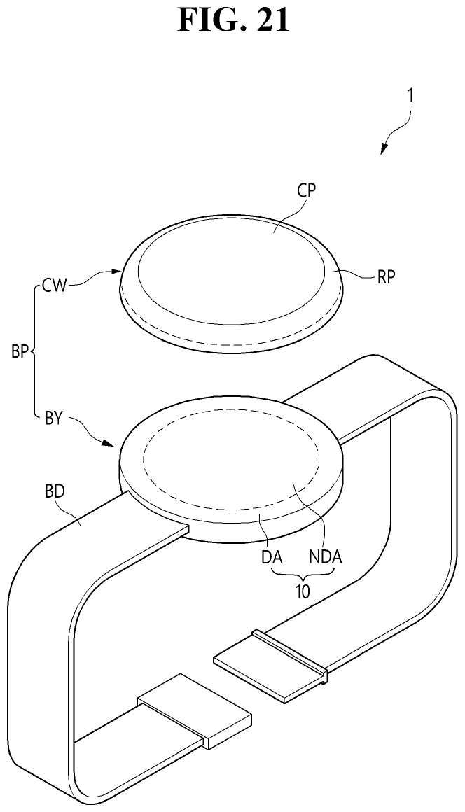

FIG. 21 is an exploded schematic perspective view of a display device according to an embodiment.

Referring to FIG. 21, a display device 1 according to an embodiment may include a body unit BP and a band BD. Although a smart watch is shown in FIG. 21 as an example of the display device 1, embodiments are not limited thereto. According to another embodiment, the display device 1 may be a variety of display devices such as a smart phone, a television, and a computer.

The body unit BP may include a display panel 10, on which images are displayed, and a cover glass CW disposed on the display panel 10.

The display panel 10 may be a screen on which various information, contents, user interfaces, etc. as images are displayed. The display panel 10 may be positioned at the center portion of the upper surface of a body BY. The display panel 10 may be an organic light-emitting display panel, a liquid-crystal display panel, etc., but embodiments are not limited thereto. The display panel 10 may include a display area DA where images are displayed, and a non-display area NDA disposed around the display area DA. Although the display panel 10 has a generally circular shape in the example shown in FIG. 21, embodiments are not limited thereto. The display panel 10 may have various shapes, for example, a polygonal shape such as a quadrangle or an ellipse.

The cover glass CW may be disposed above the display panel 10 to protect the display panel 10 and may transmit the light exiting from the display panel 10. As described above, the cover glass CW may include a light-blocking portion to block some of the light exiting from the display panel 10. The cover glass CW may include a rigid material such as glass, plastic, and quartz.

The cover glass CW may be disposed to overlap the display panel 10 and may cover the front surface of the display panel 10. The cover glass CW may have a shape similar to that of the display panel 10 and may be larger than the display panel 10. For example, the cover glass CW may protrude outward from the display panel 10. The shape of the cover glass CW may be identical to (or similar to) that of the body unit BP when viewed from the top (or in plan view). For example, the cover glass CW may have a substantially circular shape, but embodiments are not limited thereto. It may have various shapes, for example, a polygonal shape such as a quadrangle or an ellipse.

The cover glass CW may include a central portion CP and a peripheral portion RP around the central portion CP.

The central portion CP may be positioned at the center portion of the cover glass CW and may be substantially flat. The central portion CP may correspond to the display area DA of the display panel 10. For example, the central portion CP of the cover glass CW may cover (e.g., entirely cover) the display area DA of the display panel 10, but embodiments are not limited thereto. The central portion CP of the cover glass CW may cover only a part of the display area DA of the display panel 10.

The peripheral portion RP may be disposed to surround the central portion CP. The peripheral portion RP may be bent from the central portion CP. The peripheral portion RP may be bent from the edge portion of the central portion CP. In some embodiments, the peripheral portion RP may include a curved surface having a curvature (or selectable curvature), and the other portion may be flat. The degree (or angle) at which the peripheral portion RP is bent from the central portion CP may be an obtuse angle, but embodiments are not limited thereto. It may be a right angle or an acute angle. According to another embodiment, the peripheral portion RP may include a curved surface having a curvature (or selectable curvature). The curvature of the peripheral portion RP may be constant across different regions, but embodiments are not limited thereto. The curvature of the peripheral portion RP may be varied across different regions.

The band BD may be a part for fixing the body unit BP to a user's wrist, etc., and may be, for example, one of a strap, a chain, and a bracelet.

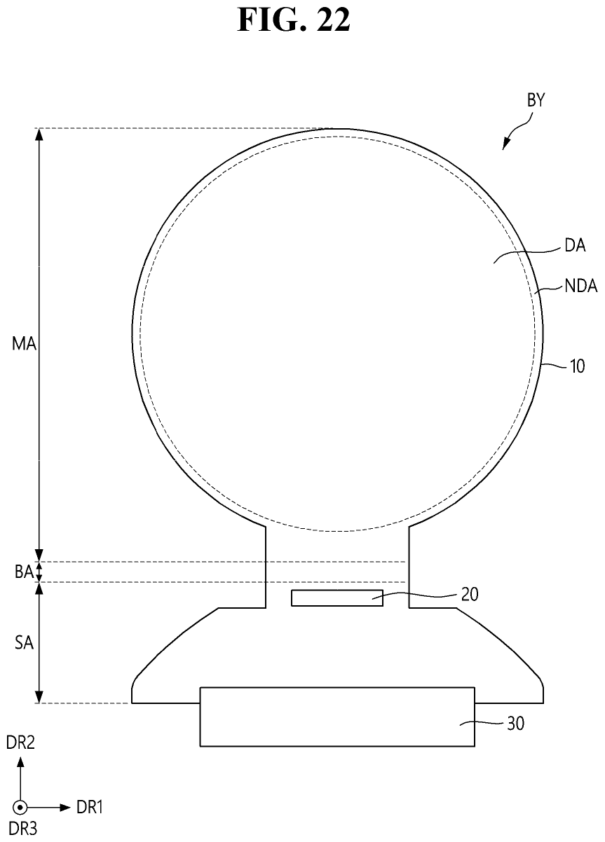

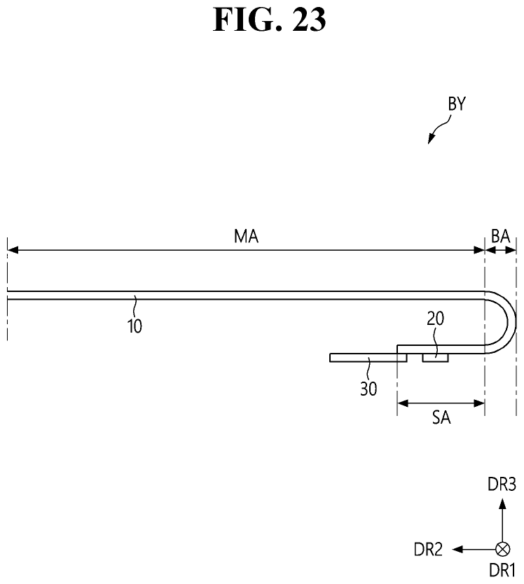

FIG. 22 is a schematic plan view of a display device according to an embodiment. FIG. 23 is a schematic cross-sectional view of a part of a display device according to an embodiment.

Referring to FIGS. 22 and 23, the body BY may include a display panel 10, a driver chip 20, and a driving board 30.

Examples of the display panel 10 may include an organic light-emitting display panel, a micro LED display panel, a nano LED display panel, a quantum-dot display panel, a liquid-crystal display panel, a plasma display panel, a field emission display panel, an electrophoretic display panel, an electrowetting display panel, etc. In the following description, an organic light-emitting display panel may be implemented as an example of the display panel 10, but embodiments are not limited thereto. Any other display panel may be implemented as long as the technical idea of the disclosure may be equally applied.

The display panel 10 may include a display area DA and a non-display area NDA. In the display area DPA, images may be displayed. In the non-display area NDA, image may not be displayed.

The display area DA may include a circular shape when viewed from the top (or in plan view). However, embodiments are not limited thereto. The display area DA may have various shapes such as a rectangle or a rectangle with rounded corners, a square, other polygons or an ellipse.

The non-display area NDA may be disposed around the display area DA. The non-display area NDA may be a bezel. The non-display area NDA may surround the display area DA. However, embodiments are not limited thereto. For example, the non-display area NDA may not be disposed in at least a part of the peripheral area of the display area DA.

In the non-display area NDA, signal lines for applying signals to the display area DA (e.g., display area or touch area) or driving circuits may be disposed. In another example, the non-display area NDA may include a part of the touch area, and a sensor member such as a pressure sensor may be disposed in that part.

The display panel 10 may include pixels. The pixels may be arranged in a matrix. The shape of each pixel may be a rectangle or a square when viewed from the top (or in plan view), but embodiments are not limited thereto. Each pixel may have a diamond shape having sides, which are inclined with respect to the second direction DR2 or the first direction DR1. Each pixel may include an emission area. Each emission area may have the same shape as or a different shape from the shape of the pixels. For example, in case that the pixels have a rectangular shape, the shape of the emission area of each of the pixels may have various shapes such as a rectangle, a diamond, a hexagon, an octagon, and a circle.

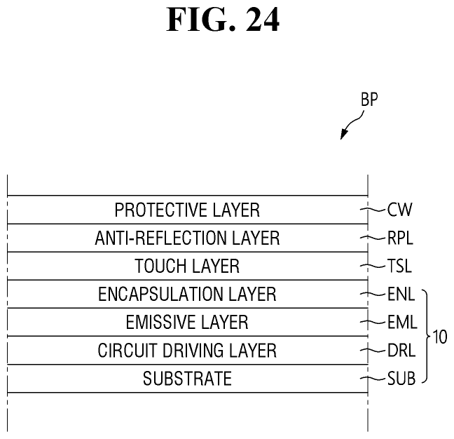

The body BY may further include a touch member for sensing a touch input. The touch member may be implemented as a touch layer TSL (see FIG. 24) on the display panel 10. For example, the touch layer TSL (see FIG. 24) may be formed integrally with the display panel 10. However, embodiments are not limited thereto. The touch member may be implemented as a panel or film separated from the display panel 10 and attached to the display panel 10. In the following embodiment, the touch member may be implemented as the touch layer TSL (see FIG. 24), but embodiments are not limited thereto.

In the touch area, a touch input may be sensed. The touch area may overlap the display area DA. In the display area DA, images may be displayed and a touch input may be sensed as well.

The display panel 10 may include a flexible substrate including a flexible polymer material such as polyimide. Accordingly, the display panel 10 may be curvable, bendable, foldable, or rollable.

The display panel 10 may include a bending area BA. The display panel 10 may be divided into a main area MA positioned on a side of the bending area BA in the second direction DR2 and a subsidiary area SA positioned on the opposite side of the bending area BA in the second direction DR2.

The display area of the display panel 10 may be positioned in the main area MA. According to an embodiment, the edge portions of the display area in the main area MA, the entire bending area BA and the entire subsidiary area SA may be the non-display area. However, embodiments are not limited thereto. The bending area BA and/or the subsidiary area SA may also include the display area.

The main area MA may have a shape generally similar to the outer shape of the body when viewed from the top (or in plan view). The main area MA may be a flat area positioned in a plane. However, embodiments are not limited thereto. At least one of the edge portions of the main area MA except for the edge portion (or side) connected to the bending area BA may be bent to form a curved surface or may be bent at a right angle.

In case that at least one of the edge portions of the main area MA except for the edge portion (or side) connected to the bending area BA is curved or bent, the display area may also be disposed at the edge portion. However, embodiments are not limited thereto. The curved or bent edge portion may be the non-display area that does not display image, or the display area and the non-display area may be disposed together.

The bending area BA may be connected to the second side of the main area MA in the second direction DR2. For example, the bending area BA may be connected to the lower shorter side of the main area MA. The width of the bending area BA (e.g., the width in the first direction DR1) may be smaller than the width of the main area MA (e.g., the width in the first direction DR1) adjacent to the bending area BA. The portions where the main area MA meets the bending area BA may be cut in an L-shape.

In the bending area BA, the display panel 10 may be bent downward in the thickness direction, i.e., in the direction away from the display surface having a curvature. Although the bending area BA may have a constant radius of curvature, embodiments are not limited thereto. It may have different radii of curvature for different sections. As the display panel 10 is bent at the bending area BA, the surface of the display panel 10 may be reversed. For example, the surface of the display panel 10 facing upward may be bent such that the surface of the display panel 10 may face outward in the bending area BA and then may face downward in the subsidiary area SA.

The subsidiary area SA may be extended from the bending area BA. The subsidiary area SA may be extended in a direction parallel to the main area MA from the end portion of the bending region. The subsidiary area SA may overlap the main area MA in the thickness direction of the display panel 10. The width of the subsidiary area SA (the width in the first direction DR1) may be increased away from the bending area BA. However, embodiments are not limited thereto.

A driver chip 20 may be disposed in the subsidiary area SA. The driver chip 20 may include an integrated circuit for driving the display panel 10. The integrated circuit may include an integrated circuit for display and/or an integrated circuit for a touch unit. However, embodiments are not limited thereto. The integrated circuit for a display and the integrated circuit for a touch unit may be provided as separate chips or may be integrated into a single chip.

A pad area may be positioned at the end portion of the subsidiary area SR of the display panel 10. The pad area may include display signal line pads and touch signal line pads. The driving board 30 may be connected to the pad area at the end portion of the subsidiary area SA of the display panel 10. The driving board 30 may be a flexible printed circuit board or a film.

FIG. 24 is a schematic cross-sectional view showing an example of a stack structure of a body unit according to an embodiment.

Referring to FIG. 24, the body unit BP may include a substrate SUB, a circuit-driving layer DRL, an emissive layer EML, an encapsulation layer ENL, a touch layer TSL, an anti-reflection layer RPL, and a cover glass CW, which are stacked on one another. The display panel 10 may include the substrate SUB, the circuit-driving layer DRL, the emissive layer EML, and the encapsulation layer ENL.

The substrate SUB may support elements disposed thereon.

The circuit-driving layer DRL may be disposed on the substrate SUB. The circuit-driving layer DRL may include a circuit for driving an emissive layer EML of each pixel. The circuit-driving layer DRL may include thin-film transistors.

The emissive layer EML may be disposed on the circuit-driving layer DRL. The emissive layer EML may include an organic emitting layer. The emissive layer EML may emit light having various luminances according to driving signals transmitted from the circuit-driving layer DRL.

The encapsulation layer ENL may be disposed on the emissive layer EML. The encapsulation layer ENL may include an inorganic film or a stack of an inorganic film and an organic film. As another example, glass or an encapsulation film may be implemented as the encapsulation layer ENL.

The touch layer TSL may be disposed on the encapsulation layer ENL. The touch layer TSL may sense a touch input and may perform the functions of the touch member. The touch layer TSL may include sensing regions and sensing electrodes.

The anti-reflection layer RPL may be disposed on the touch layer TSL. The anti-reflection layer RPL may function to reduce reflection of external light. The anti-reflection layer RLP may be attached in the form of a polarizing film. For example, the anti-reflection layer RLP may polarize the light passing therethrough, and the anti-reflection layer RPL may be attached on the touch layer TSL through an adhesive layer. The anti-reflection layer RPL in the form of a polarizing film may be omitted. The anti-reflection layer RPL may function to reduce reflection of external light.

However, embodiments are not limited thereto. The anti-reflection layer RPL may be stacked in the form of a color filter layer. For example, the anti-reflection layer RPL may include a color filter that selectively transmits light of a certain wavelength, etc.

The cover glass CW may be disposed on the anti-reflection layer RPL. The cover glass CW may include the light-blocking portions BM1 and BM2 (see FIG. 20) printed by the printing apparatus 1000 (see FIG. 1) and the method S1 of fabricating a cover glass according to the above-described embodiments.

In concluding the detailed description, those skilled in the art will appreciate that many variations and modifications may be made to the embodiments without substantially departing from the principles of the invention. Therefore, the disclosed embodiments of the invention are used in a generic and descriptive sense only and not for purposes of limitation.

What is claimed is:

1. A printing apparatus comprising:
a jig comprising:
a base comprising a groove, and
a protrusion disposed on a surface of the base; and
a pad disposed on the jig,
wherein the protrusion surrounds the groove.

2. The printing apparatus of claim 1, wherein
the protrusion comprises:
a protruding portion surrounding the groove, and
a receiving portion surrounded by the protruding portion, and
a width of the receiving portion is larger than a width of the groove.

3. The printing apparatus of claim 2, wherein at least a portion of the protruding portion overlaps the groove.

4. The printing apparatus of claim 2, wherein a step portion is formed between the protruding portion and the groove.

5. The printing apparatus of claim 2, wherein the protruding portion is spaced apart from the groove.

6. The printing apparatus of claim 5, wherein the protruding portion is spaced apart from the groove by about 5 mm or less.

7. The printing apparatus of claim 2, wherein the protruding portion has a shape that is convex away from the groove.

8. The printing apparatus of claim 7, wherein
the protruding portion comprises:
a first surface spaced apart from the groove;
a second surface facing the first surface and being adjacent to the groove; and
a third surface between the first surface and the second surface, and
the first surface and the second surface are curved to be convex away from the groove.

9. The printing apparatus of claim 8, wherein a first distance between a first point, in which the first and third surfaces meet, and a second point, which is an outermost position of the first surface, is greater than 0 mm.

10. The printing apparatus of claim 8, wherein an extension direction of the third surface is perpendicular to an extension direction of the surface of the base.

11. The printing apparatus of claim 2, wherein
the protrusion further comprises an opening surrounded by the protruding portion, and
a width of the opening is larger than a width of the pad.

12. The printing apparatus of claim 2, wherein
the protruding portion comprises:
a first extension portion disposed on the base; and
a second extension portion extended from the first extension portion, and
an extension direction of the first extension portion and an extension direction of the second extension portion are different from each other.

13. The printing apparatus of claim 12, wherein the extension direction of the second extension portion is parallel to the extension direction of the surface of the base.

14. The printing apparatus of claim 12, wherein at least a portion of the second extension portion overlaps the groove.

15. The printing apparatus of claim 12, wherein the first extension portion is spaced apart from the groove.

16. The printing apparatus of claim 1, wherein the groove comprises a curved portion having a curvature.

17. The printing apparatus of claim 1, wherein the protrusion has a pot shape having a width that decreases as being closer to an upper portion and a lower portion.

18. A method for fabricating a cover glass, the method comprising:
preparing a printing apparatus and a window, the printing apparatus comprising:
a jig comprising:
a base comprising a groove, and
a protrusion disposed on a surface of the base, the protrusion surrounding the groove; and
a pad disposed on the jig; and
applying ink to the pad and printing the ink on the window.

19. A display device comprising:
a cover glass comprising a light-blocking portion printed by a printing apparatus, the printing apparatus comprising:
a jig comprising:
a base comprising a groove, and
a protrusion disposed on a surface of the base, the protrusion surrounding the groove; and
a pad disposed on the jig, and
a display panel covered by the cover glass, wherein
the cover glass further comprises a window that transmits light emitted from the display panel, and
the light-blocking portion is disposed along an edge portion of the window and at least partially blocks the light emitted from the display panel.

20. The display device of claim 19, wherein a minimum thickness of the light-blocking portion is equal to or greater than about 2 μm.
